(19) United States
(12) Patent Application Publication
(10) Pub. No.: US 2025/0321262 A1
(43) Pub. Date: Oct. 16, 2025

(54) METHOD AND APPARATUS FOR CIRCUIT BOARD DETECTION, COMPUTER DEVICE, STORAGE MEDIUM, AND PROGRAM PRODUCTS

(71) Applicant: Glenfly Tech Co., Ltd., Shanghai (CN)

(72) Inventor: Yuan JIANG, Shanghai (CN)

(21) Appl. No.: 18/787,451

(22) Filed: Jul. 29, 2024

(30) Foreign Application Priority Data
Apr. 12, 2024 (CN) 202410445394.5

(51) Int. Cl. G01R 31/28

(52) U.S. Cl. CPC G01R 31/2813; G01R 31/2806; G01R 31/2815

(57) ABSTRACT

The present disclosure relates to a method and apparatus for circuit board detection, a computer device, a storage medium, and a program product. The method includes: receiving a detection instruction; obtaining position information of board boundary corresponding to the at least one connector and preset cable boundary information corresponding to the at least one connector; detecting the at least one connector according to the position information corresponding to the board boundary of the at least one connector and the preset cable boundary information corresponding to the at least one connector to determine detection results of multiple detection items corresponding to the at least one connector, each detection item corresponding to a DFM abnormality type of connector; and determining a target detection result of the at least one connector according to the detection results of the multiple detection items corresponding to the at least one connector.

### CROSS-REFERENCE TO RELATED APPLICATIONS

The present application claims priority to Chinese patent application No. 2024104453945, filed on Apr. 12, 2024, the entire content of which is incorporated herein by reference.

### TECHNICAL FIELD

The present disclosure relates to the field of chips and related technologies, particularly to a method and apparatus for circuit board detection, a computer device, a storage medium, and a program product.

### BACKGROUND

As a design and debugging tool for Printed Circuit Boards (PCBs), Electronic Design Automation (EDA) is increasingly involved in various stages of hardware system design and debugging. The implementation platform of the EDA is a PCB board, and Design for Manufacture (DFM) is a key factor in determining the quality of PCB board.

In related technologies, DFM detection involves a detection of the direction and position of a connector on a PCB board. Traditional detection methods mainly rely on manual work. However, relying solely on manual work for detecting the direction and position of the connector is heavily dependent on the habits and styles of individual detection personnel, which may lead to problems such as negligence, omissions, etc., resulting in low detection accuracy.

### SUMMARY

In a first aspect, the present disclosure provides a method for circuit board detection. The method includes:
receiving a detection instruction, the detection instruction being configured to instruct a detection of at least one connector on a circuit board to be detected;
obtaining position information of board boundary corresponding to the at least one connector and preset cable boundary information corresponding to the at least one connector;
detecting the at least one connector according to the position information the board boundary of corresponding to the at least one connector and the preset cable boundary information corresponding to the at least one connector to determine detection results of multiple detection items corresponding to the at least one connector, each detection item corresponding to a DFM abnormality type of connector; and
determining a target detection result of the at least one connector according to the detection results of the multiple detection items corresponding to the at least one connector.

In an embodiment, after receiving the detection instruction, the method further includes: obtaining identification information of various components of the circuit board to be detected; and identifying the at least one connector from the various components of the circuit board to be detected according to the identification information of the various components of the circuit board to be detected and naming feature information corresponding to the connector.

In an embodiment, the multiple detection items include a first detection item, detecting the at least one connector according to the position information of the board boundary corresponding to the at least one connector and the preset cable boundary information corresponding to the at least one connector to determine the detection results of the multiple detection items corresponding to the at least one connector includes:
determining coordinates of a set center point of the at least one connector according to the preset cable boundary information corresponding to the at least one connector; and
determining the detection result of the first detection item corresponding to the at least one connector according to the coordinates of the set center point of the at least one connector and the position information of the board boundary corresponding to the at least one connector.

In an embodiment, the set center point is the center point of the preset cable boundary, and the position information of the board boundary includes position coordinates of the board boundary. Determining the detection result of the first detection item corresponding to the at least one connector according to the coordinates of the set center point of the at least one connector and the position information of the board boundary corresponding to the at least one connector includes:
comparing the coordinates of the set center point with the position coordinates of the board boundary corresponding to the at least one connector to determine whether the set center point is within the board boundary;
determining that the first detection item of the at least one connector corresponding to the set center point is normal if the set center point is within the board boundary; and
determining that the first detection item of the at least one connector corresponding to the set center point is abnormal if the set center point is outside the board boundary.

In an embodiment, the multiple detection items include a second detection item, detecting the at least one connector according to the position information of the board boundary corresponding to the at least one connector and the preset cable boundary information corresponding to the at least one connector to determine the detection results of the multiple detection items corresponding to the at least one connector includes:
determining coordinates of a board edge corresponding to the at least one connector according to the position information of the board boundary of the at least one connector; and
determining the detection result of the second detection item corresponding to the at least one connector according to the preset cable boundary information corresponding to the at least one connector and the coordinates of the board edge corresponding to the at least one connector.

In an embodiment, the preset cable boundary information includes coordinates of a preset cable boundary, and the coordinates of the board edge are coordinates of the board boundary on the side where the connector is located. Determining the detection result of the second detection item corresponding to the at least one connector according to the preset cable boundary information corresponding to the at least one connector and the coordinates of the board edge corresponding to the at least one connector includes:
comparing the coordinates of the preset cable boundary corresponding to the at least one connector with the coordinates of the board edge corresponding to the at least one connector to confirm whether the coordinates of the preset cable boundary of the at least one connector are outside the board edge;
determining that the second detection item of the connector is normal if all the coordinates of the preset cable boundary of the at least one connector are outside the board edge; and
determining that the second detection item of the at least one connector is abnormal if any of the coordinates of the preset cable boundary of the at least one connector is within the board edge.

In an embodiment, there are multiple connectors, and the multiple detection items include a third detection item. Detecting the at least one connector according to the position information of the board boundary corresponding to the at least one connector and the preset cable boundary information corresponding to the at least one connector to determine the detection results of the multiple detection items corresponding to the at least one connector includes:
determining an interference relationship between each pair of connectors among the multiple connectors according to the position information of the board boundaries corresponding to the multiple connectors and the preset cable boundary information corresponding to the multiple connectors; and
determining the detection result of the third detection item corresponding to each connector according to the interference relationship between each pair of connectors among the multiple connectors.

In an embodiment, the interference relationship is that the preset cable boundaries between two connectors are overlapped or partially overlapped, and determining the detection result of the third detection item corresponding to each connector according to the interference relationship between each pair of connectors among the multiple connectors includes:
determining a center point of the board according to the position information of the board boundary;
comparing the preset cable boundary information corresponding to the multiple connectors with the center point of the board to determine the position of each of the multiple connectors, the position of the connector being configured to indicate the board edge where the connector is located; and
comparing the preset cable boundary information corresponding to each pair of connectors located at the same board edge to determine the interference relationship between each pair of connectors among the multiple connectors.

In an embodiment, after determining the target detection result of the at least one connector according to the detection results of the multiple detection items corresponding to the at least one connector, the method further includes:
generating abnormal prompt information and marking information for a target connector if the target detection result of the target connector indicates that the target connector is abnormal, the abnormal prompt information being configured to indicate the DFM abnormality type of the target connector, the marking information being configured to mark the target connector in a display diagram of the circuit board to be detected; and
displaying the abnormal prompt information and the marking information on a detection page.

In an embodiment, after determining the target detection result of the at least one connector, the method further includes: generating, when the target detection result of the at least one connector indicates that the at least one connector is abnormal, a correction method for the at least one connector according to the abnormal detection item, and automatically correcting the abnormal connector according to the correction method.

In an embodiment, the preset cable boundary information is configured to indicate a preset cable boundary of the at least one connector or a preset cable boundary of an interface connection device connected to the at least one connector.

In a second aspect, the present application provides an apparatus for circuit board detection. The apparatus includes:
a receiving module configured to receive a detection instruction, wherein the detection instruction is configured to instruct a detection of at least one connector on a circuit board to be detected;
an obtaining module configured to obtain position information of board boundary corresponding to the at least one connector and preset cable boundary information corresponding to the at least one connector; and
a detection module configured to: detect the at least one connector according to the position information of the board boundary of the at least one connector and the preset cable boundary information corresponding to the at least one connector to determine detection results of multiple detection items corresponding to the at least one connector, each detection item corresponding to a DFM abnormality type of connector; and determine a target detection result of the at least one connector according to the detection results of the multiple detection items corresponding to the at least one connector.

In an embodiment, the obtaining module is also configured to identification information of various components of the circuit board to be detected, and identify the at least one connector from the various components of the circuit board to be detected according to the identification information of the various components of the circuit board to be detected and naming feature information corresponding to the connector.

In an embodiment, the multiple detection items include a first detection item, the detection module is further configured to determine coordinates of a set center point of the at least one connector according to the preset cable boundary information corresponding to the at least one connector; and determine the detection result of the first detection item corresponding to the at least one connector according to the coordinates of the set center point of the at least one connector and the position information of the board boundary corresponding to the at least one connector.

In an embodiment, the multiple detection items include a second detection item, and the detection module is further configured to determine coordinates of a board edge corresponding to the at least one connector according to the position information of the board boundary of the at least one connector; and determine the detection result of the second detection item corresponding to the at least one connector according to the preset cable boundary information corresponding to the at least one connector and the coordinates of the board edge corresponding to the at least one connector.

In an embodiment, there are multiple connectors, and the multiple detection items includes a third detection item. The detection module is further configured to determine an interference relationship between each pair of connectors among the multiple connectors according to the position information of the board boundaries corresponding to the multiple connectors and the preset cable boundary information corresponding to the multiple connectors, and determine the detection result of the third detection item corresponding to each connector according to the interference relationship between each pair of connectors among the multiple connectors.

In an embodiment, the apparatus further includes a generation module configured to generate abnormal prompt information and marking information of the target connector if the detection result of a target connector indicates that the target connector is abnormal. The abnormal prompt information is configured to indicate the DFM abnormality type of the target connector, and the marking information is configured to mark the target connector in a display diagram of the circuit board to be detected. The abnormal prompt information and the marking information are displayed on a detection page.

In an embodiment, the preset cable boundary information is configured to indicate a preset cable boundary of the at least one connector or a preset cable boundary of an interface connection device connected to the at least one connector.

In a third aspect, the present disclosure also provides a computer device. The computer device includes a memory and a processor, the memory stores a computer program, and the processor, when executing the computer program, performs the method for circuit board detection described in the first aspect.

In a fourth aspect, the present disclosure also provides a non-transitory computer-readable storage medium, on which a computer program is stored. The computer program, when executed by a processor, causes the processor to perform the method for circuit board detection described in the first aspect.

In a fifth aspect, the present application also provides a computer program product. The computer program product includes a computer program, and the computer program, when executed by a processor, causes the processor to perform the method for circuit board detection described in the first aspect.

### BRIEF DESCRIPTION OF THE DRAWINGS

FIG. 1 is a schematic flowchart of a method for circuit board detection according to a related technology.

FIG. 2 is a schematic flowchart of a method for circuit board detection according to an embodiment of the present disclosure.

FIG. 3 is a schematic diagram illustrating a directionality of a connector according to an embodiment of the present disclosure.

FIG. 4 is a schematic diagram illustrating an absolute position of a connector according to an embodiment of the present disclosure.

FIG. 5 is a schematic diagram illustrating a relative position of a connector according to an embodiment of the present disclosure.

FIG. 6 is a schematic flowchart of another method for circuit board detection according to an embodiment of the present disclosure.

FIG. 7 is a schematic flowchart of yet another method for circuit board detection according to an embodiment of the present disclosure.

FIG. 8 is a schematic flowchart of yet another method for circuit board detection according to an embodiment of the present disclosure.

FIG. 9 is a block diagram of a structure of an apparatus for circuit board detection according to an embodiment of the present disclosure.

FIG. 10 is a diagram showing an internal structural of a computer device according to an embodiment of the present disclosure.

### DETAILED DESCRIPTION OF THE EMBODIMENTS

In order to make the purpose, technical solutions, and advantages of the present disclosure clearer, the present disclosure will be described in detailed in conjunction with the accompanying drawings and embodiments. It should be understood that the specific embodiments described herein are merely used to explain the present disclosure and are not to intended to limit the present disclosure.

In the description of the present disclosure, it should be understand that if terms such as “center”, “longitudinal”, “lateral”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, “axial”, “radial”, “circumferential”, etc., are used, these terms indicate orientations or positional relationships as shown in the drawings, and are used for the purpose of describing the present disclosure and simplifying the description, not indicating or implying that the described devices or components must have specific orientations, be constructed and operated in specific orientations. Therefore, these terms should not be interpreted as limitations on the present disclosure.

In addition, if terms such as “first”, “second”, etc., are used, these terms are only used to describe sequence, not indicating or implying relative importance and specific quantities of the described technical features. Therefore, features described with “first”, “second”, etc., may include at least one of those features, whether explicitly stated or implied. In the description of the present disclosure, if the term “multiple” is used, it means at least two, such as two, three, etc., unless otherwise explicitly specified.

First, the related technology will be described below.

Design for Manufacture (DFM) is an important consideration in hardware system design that determines the final quality of a PCB board. During the DFM, a deviation in the connector direction and position due to negligence will result in abnormalities in the PCB board.

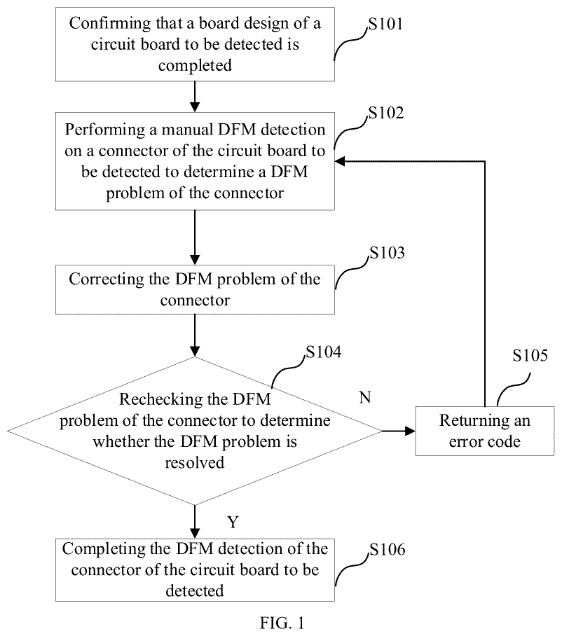

In the related technology, DFM detection involves detecting the direction and position of the connector on the PCB board, and the traditional detection method mainly relies on manual work. FIG. 1 is a schematic flowchart of a method for circuit board detection in the related technology. As shown in FIG. 1, the method for circuit board detection includes steps S101-S106.

In S101, it is confirmed that a board design of a circuit board to be detected is completed.

The circuit board to be detected may be a PCB board. Exemplarily, it is confirmed that the board design of the circuit board to be detected is completed when the draft of the circuit board to be detected is determined to be completed.

In S102, a manual DFM detection is performed on a connector of the circuit board to be detected to determine a DFM problem of the connector.

Exemplarily, a plurality of connectors on the circuit board to be detected may be manually detected one by one. For instance, based on a datasheet of the connectors and the actual requirements of the circuit board to be detected, each connector is detected to identify DFM problems such as reverse connection, overlapping interference, failure in plugging, or the like.

In S103, a correction is made to the DFM problem of the connector.

In S104, the DFM problem of the connector is rechecked to determine whether the DFM problem is resolved.

If the DFM problem is resolved, the process goes to S106, otherwise, the process goes to S105.

In S105, an error code is returned.

After S105, the process returns to S102.

Different error codes indicate different DFM abnormality types.

In S106, the DFM detection of the connector of the circuit board to be detected is completed.

However, in the related technology, the detection of the direction and position of the connector only relies on manual work, which is heavily dependent on the habits and styles of individual detection personnel and may lead to problems such as negligence and omissions, resulting in low detection accuracy.

To solve the above problems, embodiments of the present disclosure provide a method and apparatus for circuit board detection, an electronic device, a storage medium, and a program product, which automatically check detection items corresponding to multiple DFM abnormality types based on position information of the board boundary corresponding to the connector and preset cable boundary information, avoiding the negligence and omission problems in manual detection, and thus improving the detection accuracy of the connector.

The method for circuit board detection provided in the embodiments of the present disclosure can be applied in an application environment of circuit board design. After the circuit board to be detected is designed, a DFM detection can be performed on the circuit board to be detected through a terminal device. The user can input a detection instruction to the terminal device, and the detection instruction is configured to instruct the terminal device to perform a detection on multiple connectors of the circuit board to be detected. Then, the terminal device obtains position information of the board boundaries corresponding to the multiple connectors and preset cable boundary information corresponding to the multiple connectors respectively, performs a detection on each of the connectors based on the position information of the board boundaries corresponding to the multiple connectors and the preset cable boundary information corresponding to the multiple connectors, so as to determine detection results of multiple detection items corresponding to each connector, respectively. Each detection item corresponds to a DFM abnormality type of connector. Finally, the terminal device determines a target detection result for each connector, respectively, according to the detection results of the multiple detection items corresponding to each connector.

The terminal device may be, but is not limited to, various personal computers, laptops, smart phones, tablets, Internet of Things devices, and portable wearable devices. The Internet of Things devices may be smart speakers, smart TVs, smart air conditioners, smart vehicle-mounted devices, etc. The portable wearable devices may be smart watches, smart bracelets, head-mounted devices, etc.

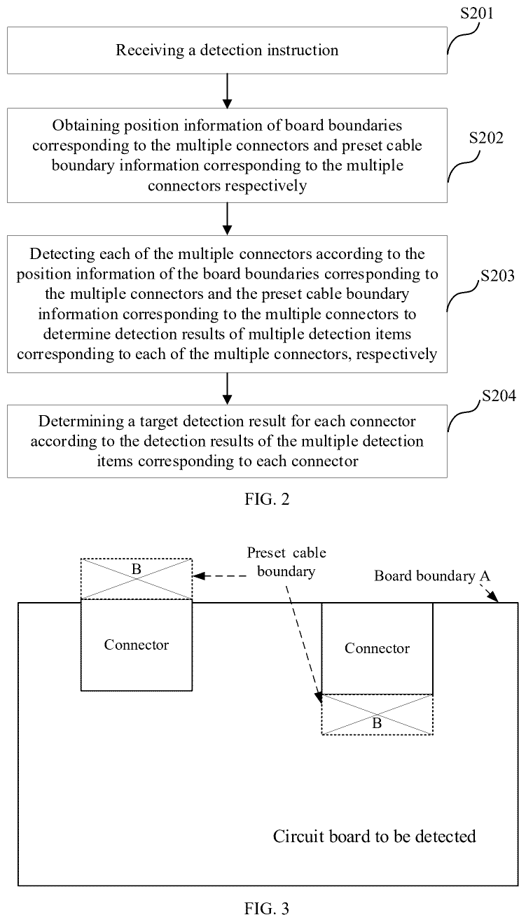

In an embodiment, as shown in FIG. 2, a method for circuit board detection is provided. The method will be illustrated by taking the application of the method to the above-mentioned terminal device as an example. The method for circuit board detection includes the following steps S201-S204.

At step S201, a detection instruction is received, which is configured to instruct a detection of multiple connectors on a circuit board to be detected.

In the present disclosure, when a circuit board needs to be detected, a user may input a detection instruction to the terminal device. The detection instruction is configured to instruct the terminal device to perform the detection on the multiple connectors of the circuit board to be detected.

The circuit board to be detected may be a PCB board, including a single-layer circuit board, a multi-layer circuit board, a rigid circuit board, a flexible circuit board, etc., and the type of the circuit board is not limited in the embodiments of the present disclosure. The connector may be a plug-in device of the circuit board to be detected.

Exemplarily, when the design of the circuit board to be detected is completed, a user may input a detection instruction through a command bar. The detection instruction may be a user-defined command ‘conn_ck’. A DFM detection program for connectors can be triggered by the detection instruction, thereby realizing the detection of multiple connectors on the circuit board to be detected.

In some embodiments, after receiving the detection instruction, the terminal device may also obtain identification information of each component of the circuit board to be detected. Then, the terminal device identifies the multiple connectors from the various components of the circuit board to be detected according to the identification information of the various components of the circuit board to be detected and naming feature information corresponding to the connectors.

The identification information may be the component name of each component of the circuit board to be detected, and the naming feature information may be a character in the component name.

It should be understood that components of the same type have the same naming feature information. Therefore, components of a specific type can be identified from the various components of the circuit board to be detected based on the naming feature information. Exemplarily, connectors typically have component names starting with the letter ‘J’, which can be used as the naming feature information. Accordingly, by determining whether the first letter of the component name is ‘J’, a quick identification can be performed to determine the connectors that begin with ‘J’.

Exemplarily, the terminal device may identify the components that begin with ‘J’ using a regular expression, and store the identified components into a connector list. If the circuit board to be detected is a multi-layer circuit board, since the connectors are all disposed on the surface, i.e., the top layer and the bottom layer of the circuit board to be detected, only the connectors on the top layer and the bottom layer of the circuit board to be detected need to be identified.

In the present disclosure, after receiving the detection instruction, the terminal device identifies the multiple connectors from various components of the circuit board to be detected based on the identification information of each of the components and the naming feature information of the connectors, so that the detection is performed only on the connectors, greatly reducing the complexity of the detection system and improving the detection efficiency.

At step S202, position information of board boundaries corresponding to the multiple connectors and preset cable boundary information corresponding to the multiple connectors are obtained, respectively.

In this step, after receiving the detection instruction, the terminal device obtains the position information of the board boundaries corresponding to the multiple connectors and the preset cable boundary information corresponding to the multiple connectors, respectively.

The position information of the board boundary includes multiple position coordinates of the board boundary. The preset cable boundary information may be a preset boundary information of a cable of the connector.

In some embodiments, the preset cable boundary information is configured to indicate a preset cable boundary of a corresponding connector or a preset cable boundary of an interface connection device connected to the corresponding connector.

The interface connection device may include connection devices such as a USB flash drive, a Universal Serial Bus (USB) network card, an adapter for a digital toggle of a High Definition Multimedia Interface (HDMI), and the like.

It should be understood that the preset cable boundary specifically refers to the boundary of the area occupied by the cable of the connector or a device connected to the connector, for example, the actual width of a USB flash drive or other connection devices.

In some embodiments, before finishing the design of the circuit board to be detected, the preset cable boundary information can be set for all connectors of the circuit board to be detected, and the preset cable boundary information can be stored in a specific storage address in the terminal device. When circuit board detection is required, the terminal device can obtain the preset cable boundary information corresponding to the multiple connectors from the specific storage address.

It should be understood that the method for obtaining the position information of the board boundaries corresponding to the multiple connectors is not limited in the present disclosure. In some embodiments, a scanning assembly can be set on the terminal device. Through the scanning assembly, the terminal device can obtain a board boundary matrix of the circuit board to be detected, thereby determining multiple position coordinates of the board boundary.

Exemplarily, the horizontal and vertical coordinates of the left, right, top and bottom sides of the frame of the circuit board to be detected can be used as the position information of the board boundary. For instance, if the board boundary of the circuit board to be detected is regular (e.g., the board boundary is a regular rectangle), the coordinates of the lower left corner and the upper right corner of the board boundary of the circuit board to be detected can be used as the position information of the board boundary, and the approximate outline of the entire board can be outlined by the coordinates of the lower left corner and the upper right corner.

At step S203, each of the multiple connectors is detected according to the position information of the board boundaries corresponding to the multiple connectors and the preset cable boundary information corresponding to the multiple connectors to determine detection results of multiple detection items corresponding to each of the multiple connectors, respectively.

Each detection item corresponds to a DFM abnormality type of connector.

It should be understood that the method for detecting each connector based on the position information of the board boundaries corresponding to the multiple connectors and the preset cable boundary information corresponding to the multiple connectors is not limited in the embodiments of the present disclosure. In the present disclosure, the connector abnormalities can be categorized to obtain multiple DFM abnormality types. According to different DFM abnormality types, different detection items are defined for detection, and different detection items adopt different detection methods.

In some embodiments, the multiple detection items include a first detection item, a second detection item, and a third detection item. The DFM abnormality type corresponding to the first detection item is the orientation abnormality of the connector, the DFM abnormality type corresponding to the second detection item is the absolute position abnormality of the connector, and the DFM abnormality type corresponding to the third detection item is the relative position abnormality of the connector.

Exemplarily, for the orientation abnormality of the connector, since it is difficult to identify the orientation of the connector during packaging, the connector may be packaged in the opposite orientation, for example, the connector that should face outward faces inward, which may cause the circuit board to be unable to be produced. Exemplarily, the absolute position abnormality of the connector is typically that a safe distance between the interface of the connector and the edge of the circuit board to be detected is too small, which results in the cable of the connector being unable to be plugged in. Exemplarily, the relative position abnormality of the connectors may be that the placement of the connectors on the circuit board to be detected is normal, but interference occurs after plugging in external cables, which results in the interfaces of the two connectors being unable to be used at the same time, severely limiting the application of the connectors.

In other embodiments, in addition to the orientation abnormality of the connector, the absolute position abnormality of the connector, and the relative position abnormality of the connector, other DFM problems can also be detected as a fourth detection item. It can be understood that the number of detection items is not limited in the present disclosure, for example, only one or two of the above-mentioned detection items may be performed in some embodiments.

In some embodiments, for the first detection item, the terminal device can first determine the coordinates of the set center point of each connector according to the preset cable boundary information corresponding to the multiple connectors. Then, the terminal device determines a detection result of the first detection item corresponding to each connector according to the coordinates of the set center point of each of the multiple connectors and the position information of the board boundary corresponding to each of the multiple connectors.

The set center point is the center point of the preset cable boundary.

Exemplarily, by comparing the coordinates of the set center point with the position information of the board boundary, it can be determined whether the set center point is within the board boundary. If the set center point is within the board boundary, it is determined that the first detection item of the connector corresponding to the set center point is normal, i.e., the connector has no orientation abnormality. If the set center point is not within the board boundary, it is determined that the first detection item of the connector corresponding to the set center point is abnormal, i.e., the connector has an orientation abnormality.

Exemplarily, FIG. 3 is a schematic diagram of a top view of a circuit board to be detected, illustrating a directionality of a connector provided in an embodiment of the present disclosure. As shown in FIG. 3, based on the preset cable boundary information corresponding to the connector, the coordinates of the set center point B of the connector can be calculated. The coordinates of the board boundary A can be obtained. Then, it is determined whether the set center point B is within the board boundary A by comparing the coordinates of the set center point B with the coordinates of the board boundary A. If the set center point B is within the board boundary A, it is determined that there is no orientation abnormality in the connector, and the detection of the first detection item is completed. If the set center point B is not within the board boundary A, it is determined that there is an orientation abnormality in the connector, and accordingly, an error code can be returned so that the user can correct and refine the circuit board to be detected based on the error code. After the correction and refinement, the first detection item of the connector can be detected again.

It can be understood that the number of connectors is not limited in this embodiment. For example, there may be one connector on the circuit board to be detected.

In some embodiments, for the second detection item, the terminal device can first determine the coordinates of the board edge corresponding to each of the multiple connectors according to the position information of the board boundary corresponding to each of the multiple connectors. Then, the terminal device determines the detection result of the second detection item corresponding to each connector according to the preset cable boundary information corresponding to each of the multiple connectors and the coordinates of the board edge corresponding to each of the multiple connectors.

The coordinates of the board edge are the coordinates of the board boundary on the side where the connector is located.

It should be understood that the method for determining the coordinates of the board edge corresponding to each of the multiple connectors according to the position information of the board boundary corresponding to each of the multiple connectors is not limited in the embodiments of the present disclosure. In some embodiments, the board edge on the side where the connector is located can be determined based on the position of the connector, and then the coordinates of the board edge on the side where the connector is located can be extracted from the position information of the board boundary.

Exemplarily, the preset cable boundary information corresponding to the connector can be compared with the coordinates of the board edge corresponding to the connector. If the preset cable of the connector is outside the board edge, it is determined that the second detection item of the connector is normal, i.e., the connector has no absolute position abnormality. If the preset cable of the connector is within the board edge, it is determined that the second detection item of the connector is abnormal, i.e., the connector has an absolute position abnormality.

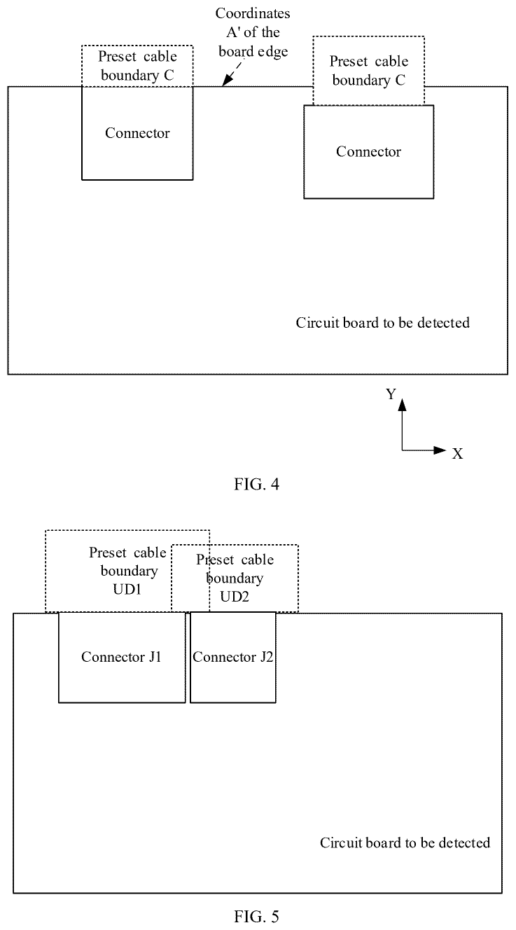

Exemplarily, FIG. 4 is a schematic diagram illustrating an absolute position of a connector provided in an embodiment of the present disclosure. As shown in FIG. 4, if the connector is located at the upper board boundary, the coordinates of the upper board boundary are extracted from the position information of the board boundary as the coordinates A′ of the board edge corresponding to the connector. Then, the preset cable boundary information C corresponding to the connector is compared with the coordinates A′ of the board edge, respectively. It can be seen that the preset cable boundary information C includes multiple coordinate values in both the Y-axis direction and X-axis direction, and the coordinates of the upper board boundary (i.e., the coordinates A′ of the board edge) have the same value in the Y-axis direction. In the Y-axis direction, if all the coordinate values of C minus A′ are greater than or equal to zero, it is determined that the preset cable of the connector is outside the board edge, and it is thus determined that the second detection item of the connector is normal, i.e., the connector has no absolute position abnormality. Accordingly, in the Y-axis direction, if any coordinate value of C minus A′ is less than zero, it is determined that the second detection item of the connector is abnormal, i.e., the connector has an absolute position abnormality. When there is an absolute position abnormality, an error code can be returned so that the user can correct and refine the circuit board to be detected based on the error code. After the correction and refinement, the second detection item of the connector can be detected again.

It can be understood that the number of connectors is not limited in this embodiment. For example, there may be one connector on the circuit board to be detected.

In some embodiments, for the third detection item, the terminal device can first determine an interference relationship between each pair of connectors among the multiple connectors according to the position information of the board boundaries corresponding to the multiple connectors and the preset cable boundary information corresponding to the multiple connectors. Then, the terminal device determines the detection result of the third detection item corresponding to each connector according to the interference relationship between each pair of connectors among the multiple connectors.

The interference relationship can be that the preset cable boundaries of two connectors are overlapped or partially overlapped.

It should be understood that the method for determining the interference relationship between each pair of connectors among the multiple connectors according to the position information of the board boundaries corresponding to the multiple connectors and the preset cable boundary information corresponding to the multiple connectors is not limited in the embodiments of the present disclosure. In some embodiments, the center point of the board can be determined according to the position information of the board boundary. Then, the preset cable boundary information corresponding to each connector is compared with the center point of the board to determine the position of the connector. The position of the connector is configured to indicate the board edge on which the connector is located. Subsequently, the preset cable boundary information corresponding to the connectors located on the same board edge are compared in pairs to determine the interference relationship between each pair of connectors among the multiple connectors.

Exemplarily, FIG. 5 is a schematic diagram of a relative position of a connector provided in an embodiment of the present disclosure. As shown in FIG. 5, a connector J1 and a connector J2 are both located at the upper board edge of the board boundary. Accordingly, multiple boundary coordinates C corresponding to the preset cable boundary UD1 of the connector J1 and multiple boundary coordinates D corresponding to the preset cable boundary UD2 of the connector J2 can be compared. If any boundary coordinate C is within the preset cable boundary UD2 composed of the multiple boundary coordinates D, or any boundary coordinate D is within the preset cable boundary UD1 composed of the multiple boundary coordinates C, it is determined that the third detection item of the connector is abnormal, i.e., the connectors have a relative position abnormality. If all boundary coordinates C are outside the preset cable boundary UD2 composed of the multiple boundary coordinates D, and all boundary coordinates D are outside the preset cable boundary UD1 composed of the multiple boundary coordinates C, it is determined that the third detection item of the connector is normal, i.e., the connectors have no relative position abnormality. When there is a relative position abnormality, an error code can be returned so that the user can correct and refine the circuit board to be detected based on the error code. After the correction and refinement, the third detection item of the connector can be detected again.

At step S204, a target detection result for each connector is determined according to the detection results of the multiple detection items corresponding to each connector.

In this step, after the terminal device determines the detection results of the multiple detection items corresponding to each connector respectively, it can determine the target detection result of each connector respectively according to the detection results of the multiple detection items corresponding to each connector.

In some embodiments, it is determined that the target detection result of the connector is abnormal if the detection result of any detection item of the connector is abnormal. It is determined that the target detection result of the connector is normal if the detection results of all the detection items of the connector are normal.

In some embodiments, after determining the target detection result of each connector, if the target detection result of a target connector indicates that the target connector is abnormal, the terminal device generates abnormal prompt information and marking information for the target connector. The abnormal prompt information is configured to indicate the abnormality type of the target connector, and the marking information is configured to mark the target connector in the display diagram of the circuit board to be detected. Then, the terminal device displays the abnormal prompt information and marking information on a detection page.

The target connector is any connector among the multiple connectors in the circuit board to be detected. The marking information can be implemented by highlighting.

Exemplarily, the abnormal prompt information may be an error code. Different abnormality types correspond to different error codes. For instance, the first detection item for the connector's orientation abnormality may correspond to an error code E-01. The second detection item for the connector's absolute position abnormality may correspond to an error code E-03. The third detection item for the relative position abnormality of the connector may correspond to an error code E-02.

In some embodiments, when the detection result of the connector is abnormal, the abnormal detection item of the connector is re-detected after a certain period of time until the DFM problems of all connectors on the circuit board to be detected are resolved.

In the embodiments of the present disclosure, the DFM detection for the connectors on the circuit board to be detected can significantly reduce the occurrence of errors and improve the success rate of the design. It is not only fast and efficient, but also stable and reliable, easy to use, and simple to operate, thus improving the overall efficiency of project design.

In some embodiments, after determining the target detection result for the connector, the method further includes: when the target detection result for the connector indicates that the connector is abnormal, generating a correction method for the connector according to the abnormal detection item, and automatically correcting the connector. Furthermore, the correction may be displayed to the user. Exemplarily, when it is determined that the connector has an orientation abnormality, the terminal device can automatically correct the orientation of the connector. When it is determined that the connector has an absolute position abnormality, the terminal device can automatically correct the position of the connector to resolve the abnormality. When it is determined that the connector has a relative position abnormality, the position of the connector is automatically corrected. For example, if it is determined that there is an interference between two connectors, the position of at least one of the two connectors is automatically corrected to eliminate the interference between the two connectors.

Automatic correction during the design process of the circuit board can be achieved by automatically correcting the abnormal connectors.

In addition, the method for circuit board detection has the following advantages. First, it can reduce the probability of error. Since the DFM problems are divided into multiple detection items, the complexity is reduced, which can reduce the losses caused by negligence in manual detection. Second, it has wide applicability. DFM problems may be encountered in various projects, such as identifying whether the interface is inside or outside the board, making it widely applicable. Third, it can be self-iterated. Through the branch processing of each detection item, it is possible to check self-iteratively, enabling checking while designing, which can reduce the occurrence of errors and significantly improve efficiency. Fourth, it has strong scalability. The method for circuit board detection can not only be used on various EDA platforms (such as the Cadence platform), but also reserve sufficient interfaces, providing strong scalability to add functions according to actual needs. Fifth, it is highly targeted, addressing the most significant issues in connector DFM for PCB, and it is suitable for DFM detection of PCB boards of various types and fields.

According to the method for circuit board detection provided in the embodiments of the present disclosure, a detection instruction is received, which is configured to instruct the detection of multiple connectors on a circuit board to be detected. Position information of the board boundaries corresponding to the multiple connectors and preset cable boundary information corresponding to the multiple connectors are obtained, respectively. Each of the multiple connectors is detected according to the position information of the board boundaries corresponding to the multiple connectors and the preset cable boundary information corresponding to the multiple connectors, so as to determine the detection results of multiple detection items corresponding to each of the multiple connectors, respectively. Each detection item corresponds to a DFM abnormality type of connector. A target detection result of each of the multiple connectors is determined according to the detection results of the multiple detection items corresponding to each of the multiple connectors. By the method for circuit board detection, based on the position information of the board boundary corresponding to the connector and the preset cable boundary information, the detection items corresponding to multiple DFM abnormality types are automatically detected, avoiding the problems of negligence and omissions in manual detection, thereby improving the detection accuracy of the connector.

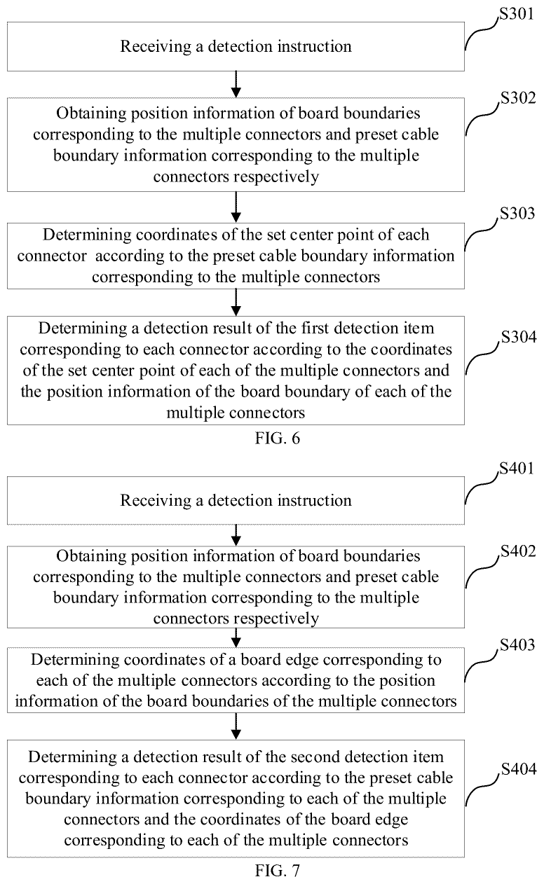

The detection process of the first detection item in the circuit board detection will be described below. The DFM abnormality type corresponding to the first detection item is orientation abnormality of the connector. FIG. 6 is a flow chart of another method for circuit board detection provided in an embodiment of the present disclosure. As shown in FIG. 6, the method for circuit board detection includes steps S301 to S304.

At step S301, a detection instruction is received. The detection instruction is configured to instruct a detection of multiple connectors on a circuit board to be detected.

At step S302, position information of board boundaries corresponding to the multiple connectors and preset cable boundary information corresponding to the multiple connectors are obtained, respectively.

At step S303, coordinates of the set center point of each connector are determined according to the preset cable boundary information corresponding to the multiple connectors.

The set center point is the center point of the preset cable boundary.

At step S304, a detection result of the first detection item corresponding to each connector is determined according to the coordinates of the set center point of each of the multiple connectors and the position information of the board boundary of each of the multiple connectors.

Exemplarily, by comparing the coordinates of the set center point with the position information of the board boundary, it can be determined whether the set center point is within the board boundary. If the set center point is within the board boundary, it is determined that the first detection item of the connector corresponding to the set center point is normal, i.e., the connector has no orientation abnormality. If the set center point is not within the board boundary, it can be determined that the first detection item of the connector corresponding to the set center point is abnormal, i.e., the connector has an orientation abnormality.

The detection process of the second detection item in the circuit board detection will be described below. The DFM abnormality type corresponding to the second detection item is the absolute position abnormality of the connector. FIG. 7 is a flow chart of another method for circuit board detection provided in an embodiment of the present disclosure. As shown in FIG. 7, the method for circuit board detection includes steps S401 to S404.

At step S401, a detection instruction is received. The detection instruction is configured to instruct a detection of multiple connectors on a circuit board to be detected.

At step S402, position information of board boundaries corresponding to the multiple connectors and preset cable boundary information corresponding to the multiple connectors are obtained, respectively.

At step S403, coordinates of a board edge corresponding to each of the multiple connectors are determined according to the position information of the board boundaries of the multiple connectors.

The coordinates of the board edge are the coordinates of the board boundary on the side where the connector is located.

It should be understood that the method for determining the coordinates of the board edge corresponding to each of the multiple connectors according to the position information of the board boundaries of the multiple connectors is not limited in the embodiments of the present disclosure. In some embodiments, the board edge on the side where the connector is located can be determined based on the position of the connector, and then the coordinates of the board edge on the side where the connector is located can be extracted from the position information of the board boundary.

At step S404, a detection result of the second detection item corresponding to each connector is determined according to the preset cable boundary information corresponding to each of the multiple connectors and the coordinates of the board edge corresponding to each of the multiple connectors.

Exemplarily, the preset cable boundary information corresponding to the connector can be compared with the coordinates of the board edge corresponding to the connector. If the preset cable of the connector is outside the board edge, it is determined that the second detection item of the connector is normal, i.e., the connector has no absolute position abnormality. If the preset cable of the connector is within the board edge, it is determined that the second detection item of the connector is abnormal, i.e., the connector has an absolute position abnormality.

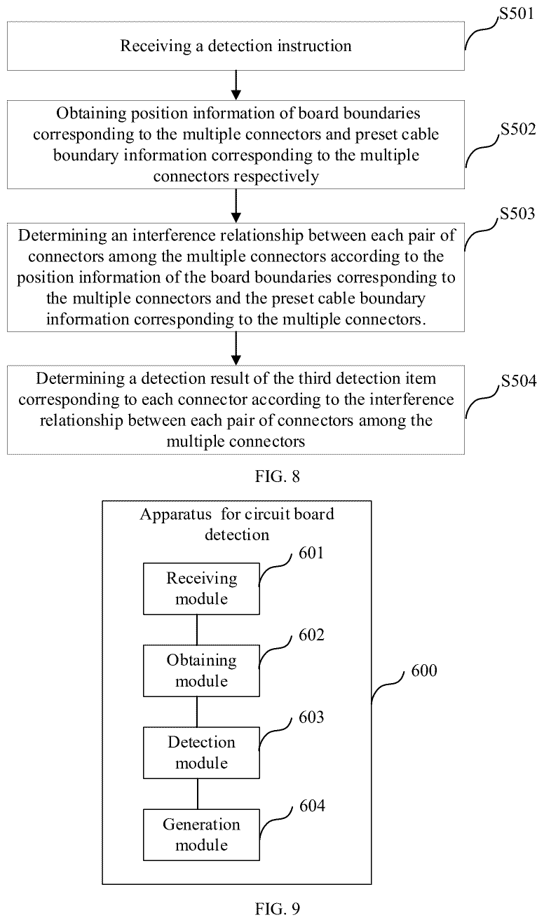

The detection process of the third detection item in the circuit board detection will be described below. The DFM abnormality type corresponding to the third detection item is relative position abnormality of the connector. FIG. 8 is a flow chart of another method for circuit board detection provided in an embodiment of the present disclosure. As shown in FIG. 8, the method for circuit board detection includes steps S501 to S504.

At step S501, a detection instruction is received. The detection instruction is configured to instruct a detection of multiple connectors on a circuit board to be detected.

At step S502, position information of board boundaries corresponding to the multiple connectors and preset cable boundary information corresponding to the multiple connectors are obtained, respectively.

At step S503, an interference relationship between each pair of connectors among the multiple connectors is determined according to the position information of the board boundaries corresponding to the multiple connectors and the preset cable boundary information corresponding to the multiple connectors.

The interference relationship can be that the preset cable boundaries of the two connectors are overlapped or partially overlapped.

It should be understood that the method for determining the interference relationship between each pair of connectors among the multiple connectors according to the position information of the board boundaries corresponding to the multiple connectors and the preset cable boundary information corresponding to the multiple connectors is not limited in the embodiments of the present disclosure. In some embodiments, the center point of the board can be determined according to the position information of the board boundary. Then, the preset cable boundary information corresponding to the connector is compared with the center point of the board to determine the position of the connector. The position of the connector is configured to indicate the board edge on which the connector is located. Subsequently, the preset cable boundary information corresponding to the connectors located on the same board edge are compared in pairs to determine the interference relationship between each pair of connectors among the multiple connectors.

At step S504, a detection result of the third detection item corresponding to each connector is determined according to the interference relationship between each pair of connectors among the multiple connectors.

According to the method for circuit board detection provided in the embodiments of the present disclosure, a detection instruction is received, which is configured to instruct the detection of multiple connectors on a circuit board to be detected. Position information of the board boundaries corresponding to the multiple connectors and preset cable boundary information corresponding to the multiple connectors are obtained, respectively. Each of the multiple connectors is detected according to the position information of the board boundaries corresponding to the multiple connectors and the preset cable boundary information corresponding to the multiple connectors, so as to determine the detection results of multiple detection items corresponding to each of the multiple connectors, respectively. Each detection item corresponds to a DFM abnormality type of connector. A target detection result of each of the multiple connectors is determined according to the detection results of the multiple detection items corresponding to each of the multiple connectors. By the method for circuit board detection, based on the position information of the board boundary corresponding to the connector and the preset cable boundary information, the detection items corresponding to multiple DFM abnormality types are automatically detected, avoiding the problems of negligence and omissions in manual detection, thereby improving the detection accuracy of the connector.

It should be understood that, although the steps in the flowcharts involved in the above embodiments are sequentially shown by the indications of the arrows, these steps are not necessarily executed in the order indicated by the arrows. Unless explicitly stated herein, the execution of these steps is not strictly limited to the order, and the steps may be executed in other orders. Moreover, at least a part of the steps in the flowcharts involved in the above embodiments may include multiple steps or multiple stages, and these steps or stages are not necessarily executed and completed at the same time, but may be performed at different times. The execution order of these steps or stages is not necessarily sequential, but may be performed alternately or in turn with other steps or at least a part of the steps or stages of the other steps.

Based on the same inventive concept, the embodiments of the present disclosure also provide an apparatus for circuit board detection for implementing the above-mentioned method for circuit board detection. The solution for solving the problem provided by the apparatus is similar to the solution described in the above method, so that specific limitations in one or more embodiments of the apparatus for circuit board detection provided below can be seen in the foregoing definition of the method for circuit board detection and will not be repeated here.

In an embodiment, as shown in FIG. 9, an apparatus 600 for circuit board detection is provided, including a receiving module 601, an obtaining module 602, and a detection module 603.

The receiving module 601 is configured to receive a detection instruction. The detection instruction is configured to instruct a detection of multiple connectors on a circuit board to be detected.

The obtaining module 602 is configured to obtain position information of board boundaries corresponding to the multiple connectors and preset cable boundary information corresponding to the multiple connectors, respectively.

The detection module 603 is configured to detect each of the multiple connectors according to the position information of the board boundaries corresponding to the multiple connectors and the preset cable boundary information corresponding to the multiple connectors to determine detection results of multiple detection items corresponding to each of the multiple connectors, respectively, each detection item corresponding to a DFM abnormality type of connector; and determine a target detection result of each connector according to the detection results of the multiple detection items corresponding to each connector, respectively.

In an embodiment, the obtaining module 602 is also configured to obtain identification information of each component of the circuit board to be detected, and identify the multiple connectors from the various components of the circuit board to be detected according to the identification information of the various components of the circuit board to be detected and naming feature information corresponding to the connectors.

In an embodiment, the multiple detection items include a first detection item, a second detection item, and a third detection item. The DFM abnormality type corresponding to the first detection item is the orientation abnormality of the connector, the DFM abnormality type corresponding to the second detection item is the absolute position abnormality of the connector, and the DFM abnormality type corresponding to the third detection item is the relative position abnormality of the connector.

In an embodiment, the detection module 603 is also configured to determine the coordinates of the set center point of each of the multiple connectors according to the preset cable boundary information corresponding to the multiple connectors, and determine the detection result of the first detection item corresponding to each connector according to the coordinates of the set center point of each of the multiple connectors and the position information of the board boundary corresponding to each of the multiple connectors.

In an embodiment, the detection module 603 is also configured to determine the coordinates of the board edge corresponding to each of the multiple connectors according to the position information of the board boundary corresponding to each of the multiple connectors; and determine the detection result of the second detection item corresponding to each connector respectively according to the preset cable boundary information corresponding to each of the multiple connectors and the coordinates of the board edge corresponding to each of the multiple connectors.

In an embodiment, the detection module 603 is also configured to determine an interference relationship between each pair of connectors among the multiple connectors based on the position information of the board boundaries corresponding to the multiple connectors and the preset cable boundary information corresponding to the multiple connectors, and determine the detection result of the third detection item corresponding to each connector based on the interference relationship between each pair of connectors among the multiple connectors.

In an embodiment, the apparatus 600 for circuit board detection further includes a generation module 604 to generate abnormal prompt information and marking information for a target connector if the detection result of the target connector indicates that the target connector is abnormal. The abnormal prompt information is configured to indicate the abnormality type of the target connector, and the marking information is configured to mark the target connector in the display diagram of the circuit board to be detected. The generation module 604 displays the abnormal prompt information and the marking information on a detection page.

In some embodiments, the preset cable boundary information is configured to indicate a preset cable boundary of a corresponding connector or a preset cable boundary of an interface connection device connected to the corresponding connector.

The modules in the above apparatus for circuit board detection may be implemented in whole or in part by software, hardware, and combinations thereof. The above modules may be embedded in or independent of a processor in a computer device in the form of hardware, or may be stored in a memory of a computer device in the form of software, so as to be called by the processor to perform the operations corresponding to the above modules.

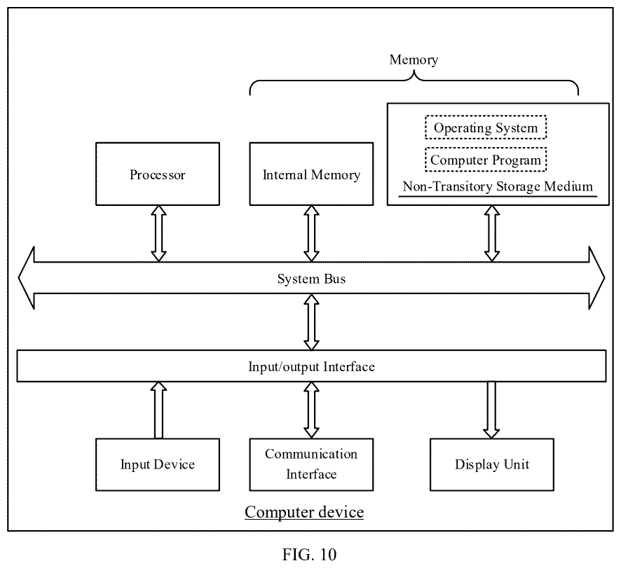

In an embodiment, a computer device is provided. The computer device may be a terminal, and its internal structure diagram may be as shown in FIG. 10. The computer device includes a processor, a memory, an input/output interface, a communication interface, a display unit, and an input device. The processor, the memory and the input/output interface are connected via a system bus, and the communication interface, the display unit and the input device are connected to the system bus via the input/output interface. The processor of the computer device is configured to provide computing and control capabilities. The memory of the computer device includes a non-transitory storage medium and an internal memory. The non-transitory storage medium stores an operating system and a computer program. The internal memory provides an environment for running the operating system and computer programs in the non-transitory storage medium. The input/output interface of the computer device is used to exchange information between the processor and external devices. The communication interface of the computer device is used to communicate with an external terminal in a wired or wireless manner. The wireless manner can be achieved by wireless fidelity (Wi-Fi), mobile cellular network, near field communication (NFC) or other technologies. When the computer program is executed by the processor, the method for circuit board detection is performed. The display unit of the computer device is used to form a visually visible picture. The display unit may be a display screen, a projection device or a virtual reality imaging device. The display screen may be a liquid crystal display screen or an electronic ink display screen. The input device of the computer device may be a touch layer covered on the display screen, or a button, a trackball or a touchpad set on the housing of the computer device, and may also be an external keyboard, a touchpad, or mouse.

Those skilled in the art should understand that the structure shown in FIG. 10 is merely a block diagram of a part of the structure related to the solution of the present disclosure, and does not constitute a limitation on the computer device to which the solution of the present disclosure is applied. A specific computer device may include more or less components than shown in the figures, or combine certain components, or have a different arrangement of components.

In an embodiment, a computer device is provided. The computer device including a memory and a processor, and a computer program is stored in the memory. The processor, when executing the computer program, performs the above-mentioned method for circuit board detection.

In an embodiment, a computer-readable storage medium is provided, in which a computer program is stored. When the computer program is executed by a processor, the above-mentioned method for circuit board detection method is performed.

In an embodiment, a computer program product is provided, which includes a computer program. The computer program, when executed by a processor, causes the processor to perform the above-mentioned method for circuit board detection.

A person skilled in the art can understand that all or part of the processes of the method in the above-mentioned embodiments can be implemented by instructing relevant hardware through a computer program. The computer program can be stored in a non-transitory computer-readable storage medium, and when executed, perform the processes of the methods in the aforementioned embodiments. Any reference to a memory, a database, or other medium used in the embodiments provided in the present disclosure may include at least one of non-transitory memory and transitory memory. The non-transitory memory may include a Read-Only Memory (ROM), a magnetic tape, a floppy disk, a flash memory, an optical memory, a high-density embedded non-transitory memory, a resistive random access memory (ReRAM), a Magnetoresistive Random Access Memory (MRAM), a Ferroelectric Random Access Memory (FRAM), a Phase Change Memory (PCM), or a graphene memory, etc. The transitory memory may include a Random Access Memory (RAM), an external cache memory, or the like. For illustration rather than limitation, the RAM may be in various forms, such as a Static Random Access Memory (SRAM) or a Dynamic Random Access Memory (DRAM). The database involved in the embodiments provided in the present disclosure may include at least one of a relational database or a non-relational database. The non-relational database may include a blockchain-based distributed database, etc., but is not limited thereto. The processors involved in the embodiments provided in present disclosure may be general-purpose processors, central processing units, graphics processors, digital signal processors, programmable logic devices, data processing logic devices based on quantum computing, etc., and is not limited to this.

The technical features in the above embodiments may be randomly combined. For concise description, not all possible combinations of the technical features in the above embodiments are described. However, provided that the combinations of the technical features do not conflict with each other, all combinations of the technical features are considered as falling within the scope recorded in this specification.

The above-mentioned embodiments only illustrate several embodiments of the present disclosure, and the descriptions of which are relatively specific and detailed, but should not be construed as limitations to the scope of the present disclosure. It should be noted that, for those skilled in the art, variations and improvements can be made without departing from the concept of the present disclosure, which all belong to the protection scope of the present disclosure. Therefore, the protection scope of the present disclosure shall be subject to the appended claims.

What is claimed is:

1. A method for circuit board detection, comprising:
receiving a detection instruction, the detection instruction being configured to instruct a detection of at least one connector on a circuit board to be detected;
obtaining position information of board boundary corresponding to the at least one connector and preset cable boundary information corresponding to the at least one connector;
detecting the at least one connector according to the position information of the board boundary corresponding to the at least one connector and the preset cable boundary information corresponding to the at least one connector to determine detection results of multiple detection items corresponding to the at least one connector, each detection item corresponding to a Design for Manufacture (DFM) abnormality type of connector; and
determining a target detection result of the at least one connector according to the detection results of the multiple detection items corresponding to the at least one connector.

2. The method according to claim 1, wherein after receiving the detection instruction, the method further comprises:
obtaining identification information of various components of the circuit board to be detected; and
identifying the at least one connector from the various components of the circuit board to be detected according to the identification information of the various components of the circuit board to be detected and naming feature information corresponding to the connector.

3. The method according to claim 1, wherein the multiple detection items comprise a first detection item, detecting the at least one connector according to the position information of the board boundary corresponding to the at least one connector and the preset cable boundary information corresponding to the at least one connector to determine the detection results of the multiple detection items corresponding to the at least one connector comprises:
determining coordinates of a set center point of the at least one connector according to the preset cable boundary information corresponding to the at least one connector; and
determining the detection result of the first detection item corresponding to the at least one connector according to the coordinates of the set center point of the at least one connector and the position information of the board boundary corresponding to the at least one connector.

4. The method according to claim 3, wherein the set center point is a center point of the preset cable boundary, the position information of the board boundary comprises position coordinates of the board boundary, and determining the detection result of the first detection item corresponding to the at least one connector according to the coordinates of the set center point of the at least one connector and the position information of the board boundary corresponding to the at least one connector comprises:
comparing the coordinates of the set center point with the position coordinates of the board boundary corresponding to the at least one connector to determine whether the set center point is within the board boundary;
determining that the first detection item of the at least one connector corresponding to the set center point is normal if the set center point is within the board boundary; and
determining that the first detection item of the at least one connector corresponding to the set center point is abnormal if the set center point is outside the board boundary.

5. The method according to claim 1, wherein the multiple detection items comprise a second detection item, detecting the at least one connector according to the position information of the board boundary corresponding to the at least one connector and the preset cable boundary information corresponding to the at least one connector to determine the detection results of the multiple detection items corresponding to the at least one connector comprises:
determining coordinates of a board edge corresponding to the at least one connector according to the position information of the board boundary of the at least one connector; and
determining the detection result of the second detection item corresponding to the at least one connector according to the preset cable boundary information corresponding to the at least one connector and the coordinates of the board edge corresponding to the at least one connector.

6. The method according to claim 5, wherein the preset cable boundary information comprises coordinates of a preset cable boundary, and the coordinates of the board edge are coordinates of the board boundary on a side where the connector is located,
wherein determining the detection result of the second detection item corresponding to the at least one connector according to the preset cable boundary information corresponding to the at least one connector and the coordinates of the board edge corresponding to the at least one connector comprises:
comparing the coordinates of the preset cable boundary corresponding to the at least one connector with the coordinates of the board edge corresponding to the at least one connector to confirm whether the coordinates of the preset cable boundary of the at least one connector are outside the board edge;
determining that the second detection item of the at least one connector is normal if all the coordinates of the preset cable boundary of the at least one connector are outside the board edge; and
determining that the second detection item of the at least one connector is abnormal if any of the coordinates of the preset cable boundary of the at least one connector is within the board edge.

7. The method according to claim 1, wherein the at least one connector comprises multiple connectors, and the multiple detection items comprise a third detection item,
wherein detecting the at least one connector according to the position information of the board boundary corresponding to the at least one connector and the preset cable boundary information corresponding to the at least one connector to determine the detection results of the multiple detection items corresponding to the at least one connector comprises:
determining an interference relationship between each pair of connectors among the multiple connectors according to the position information of the board boundaries corresponding to the multiple connectors and the preset cable boundary information corresponding to the multiple connectors; and
determining the detection result of the third detection item corresponding to each connector according to the interference relationship between each pair of connectors among the multiple connectors.

8. The method according to claim 7, wherein the interference relationship is that the preset cable boundaries between two connectors are overlapped or partially overlapped, and determining the detection result of the third detection item corresponding to each connector according to the interference relationship between each pair of connectors among the multiple connectors comprises:
determining a center point of the board according to the position information of the board boundary;
comparing the preset cable boundary information corresponding to the multiple connectors with the center point of the board to determine the position of each of the multiple connectors, the position of the connector being configured to indicate the board edge where the connector is located; and
comparing the preset cable boundary information corresponding to each pair of connectors located at the same board edge to determine the interference relationship between each pair of connectors among the multiple connectors.

9. The method according to claim 1, wherein after determining the target detection result of the at least one connector according to the detection results of the multiple detection items corresponding to the at least one connector, the method further comprises:
generating abnormal prompt information and marking information for a target connector if the target detection result of the target connector indicates that the target connector is abnormal, the abnormal prompt information being configured to indicate the DFM abnormality type of the target connector, the marking information being configured to mark the target connector in a display diagram of the circuit board to be detected; and
displaying the abnormal prompt information and the marking information on a detection page.

10. The method according to claim 1, wherein after determining the target detection result of the at least one connector, the method further comprises:
generating, when the target detection result of the at least one connector indicates that the at least one connector is abnormal, a correction method for the at least one connector according to the detection item that is abnormal, and automatically correcting the abnormal of the at least one connector according to the correction method.

11. The method according to claim 1, wherein the preset cable boundary information is configured to indicate a preset cable boundary of the at least one connector or a preset cable boundary of an interface connection device connected to the at least one connector.

12. An apparatus for circuit board detection, wherein the apparatus comprises:
a receiving module configured to receive a detection instruction, wherein the detection instruction is configured to instruct a detection of at least one connector on a circuit board to be detected;
an obtaining module configured to obtain position information of board boundary corresponding to the at least one connector and preset cable boundary information corresponding to the at least one connector; and
a detection module configured to: detect the at least one connector according to the position information of the board boundary of the at least one connector and the preset cable boundary information corresponding to the at least one connector to determine detection results of multiple detection items corresponding to the at least one connector, each detection item corresponding to a DFM abnormality type of connector; and determine a target detection result of the at least one connector according to the detection results of the multiple detection items corresponding to the at least one connector.

13. A computer device, comprising a memory and a processor, wherein the memory stores a computer program, the processor, when executing the computer program, performs a method for circuit board detection, the method comprising:
receiving a detection instruction, the detection instruction being configured to instruct a detection of at least one connector on a circuit board to be detected;
obtaining position information of board boundary corresponding to the at least one connector and preset cable boundary information corresponding to the at least one connector;
detecting the at least one connector according to the position information corresponding to the board boundary of the at least one connector and the preset cable boundary information corresponding to the at least one connector to determine detection results of multiple detection items corresponding to the at least one connector, each detection item corresponding to a Design for Manufacture (DFM) abnormality type of connector; and
determining a target detection result of the at least one connector according to the detection results of the multiple detection items corresponding to the at least one connector.

14. The computer device according to claim 13, wherein after receiving the detection instruction, the method further comprises:
obtaining identification information of various components of the circuit board to be detected; and
identifying the at least one connector from the various components of the circuit board to be detected according to the identification information of the various components of the circuit board to be detected and naming feature information corresponding to the connector.

15. The computer device according to claim 13, wherein the multiple detection items comprise a first detection item, and detecting the at least one connector according to the position information of the board boundary corresponding to the at least one connector and the preset cable boundary information corresponding to the at least one connector to determine the detection results of the multiple detection items corresponding to the at least one connector comprises:
determining coordinates of a set center point of the at least one connector according to the preset cable boundary information corresponding to the at least one connector; and
determining the detection result of the first detection item corresponding to the at least one connector according to the coordinates of the set center point of the at least one connector and the position information of the board boundary corresponding to the at least one connector.

16. The computer device according to claim 13, wherein the multiple detection items comprise a second detection item, and detecting the at least one connector according to the position information of the board boundary corresponding to the at least one connector and the preset cable boundary information corresponding to the at least one connector to determine the detection results of the multiple detection items corresponding to the at least one connector comprises:
determining coordinates of a board edge corresponding to the at least one connector according to the position information of the board boundary of the at least one connector; and
determining the detection result of the second detection item corresponding to the at least one connector according to the preset cable boundary information corresponding to the at least one connector and the coordinates of the board edge corresponding to the at least one connector.

17. The computer device according to claim 13, wherein there are multiple connectors, the multiple detection items comprise a third detection item,
wherein detecting the at least one connector according to the position information of the board boundary corresponding to the at least one connector and the preset cable boundary information corresponding to the at least one connector to determine the detection results of the multiple detection items corresponding to the at least one connector, comprises:
determining an interference relationship between each pair of connectors among the multiple connectors according to the position information of the board boundaries corresponding to the multiple connectors and the preset cable boundary information corresponding to the multiple connectors; and
determining the detection result of the third detection item corresponding to each connector according to the interference relationship between each pair of connectors among the multiple connectors.

18. The computer device according to claim 13, wherein after determining the target detection result of the at least one connector, the method further comprises:
generating, when the target detection result of the at least one connector indicates that the at least one connector is abnormal, a correction method for the at least one connector according to the abnormal detection item, and automatically correcting the abnormal connector according to the correction method.

19. A non-transitory computer-readable storage medium having a computer program stored thereon, wherein the computer program, when executed by a processor, causes the processor to perform the method according to claim 1.

20. A computer program product, comprising a computer program, wherein the computer program, when executed by a processor, causes the processor to perform the method according to claim 1.
